(19) United States
(12) Patent Application Publication
(10) Pub. No.: US 2005/0117661 A1
(43) Pub. Date: Jun. 2, 2005

(54) Soft method for variably changing a modulation method according to cell coverage range in a broadband wireless access communication system

(75) Inventor: Jae-Hyoung Kim, Anyang-si (KR)

Correspondence Address: DILWORTH & BARRESE, LLP, 333 EARLE OVINGTON BLVD., UNIONDALE, NY, 11553, US

(73) Assignee: SAMSUNG ELECTRONICS CO., LTD., GYEONGGI-DO (KR)

(21) Appl. No.: 10/993,296

(22) Filed: Nov. 19, 2004

(30) Foreign Application Priority Data
Dec. 1, 2003 (KR) 2003-86419

(51) Int. Cl. H03C 3/00

(52) U.S. Cl. 375/302; 375/298; 375/308

(57) ABSTRACT

A soft method for variably changing a modulation method in a broadband wireless access communication system. By softly applying and changing the modulation method according to a receiving error rate of a received signal in a relevant modulation method and a difference between error rates of adjacent received signals, and according to whether a power level of a received signal increases or decreases, it is possible to maintain a stable communication state and to reduce a reset time accompanied by changing the modulation method.

### PRIORITY

This application claims priority to an application entitled “Soft Method for Variably Changing Modulation Method According to Cell Coverage Range in Broadband Wireless Access Communication Systems” filed in the Korean Industrial Property Office on Dec. 1, 2003 and assigned Serial No. 2003-86419, the contents of which are hereby incorporated by reference.

### BACKGROUND OF THE INVENTION

1. Field of the Invention

The present invention relates generally to a broadband wireless access communication system, and more particularly to a method for variably changing a modulation method according to a channel environment of the broadband wireless access communication system.

2. Description of the Related Art

With the standardization of a 4th generation (4G) communication system, which is a next generation communication system, vigorous studies are being conducted to provide users with services, which have various qualities of service (QoS), at a transmission speed of approximately 10 Mbps.

Currently, the 3rd generation (3G) communication system supports a transmission speed of about 384 kbps in an outdoor channel environment having a relatively poor channel environment and supports a transmission speed of about 2 Mbps even in an indoor channel environment having a relatively good channel environment. A wireless local area network (LAN) and a wireless metropolitan area network (MAN) generally support transmission speeds of 20 Mbps to 50 Mbps.

Therefore, in the 4G communication system, new communication systems are being developed, which add mobility and increased QoS to the wireless LAN and MAN systems, securing a relatively high transmission speed. As a result, many studies are being conducted to support the high-speed communication service that the 4G communication system is intended to provide.

Because the wireless MAN system has a wide service coverage range and supports a high transmission speed, it is suitable for applications in high-speed communication services. However, the wireless MAN system does not consider the mobility of users (mobility of subscriber stations). Therefore, the wireless MAN system also does not consider a handoff resulting from high-speed movement of a subscriber station. The IEEE 802.16a standard is directed to this conventional wireless MAN system that does not consider the mobility of users.

The IEEE 802.16e standard is directed to a wireless communication technology for adding mobility to a MAN, which has a high-speed transmission function over a range of up to 75 km while including a LAN function. The IEEE 802.16e standard has been defined to provide data service, video service, voice service, etc., with a prescribed QoS in a point-to-multipoint network structure. The IEEE 802.16e standard attempts to enlarge a service environment of the subscriber station up to a cellular service environment by enabling the subscriber station to receive service even in a moving state and by adding a handoff function or the like to the subscriber station on the basis of the IEEE 802.16a standard. Main contents of the IEEE 802.16e standard include link budget improvement, a plan to enable communication during a high speed movement of the subscriber station, addition of a handoff function, addition of a low-power mode, etc.

According to the IEEE 802.16e standard, a modulation method is not fixed to any one modulation method, but can appropriately vary with a channel environment. Modulation methods that can be used in the IEEE 802.16e standard include quadrature phase shift keying (QPSK), 16 quadrature amplitude modulation (16QAM), and 64 quadrature amplitude modulation (64QAM) methods. Such modulation methods are variably applied according to a channel environment and a cell coverage range.

In the conventional modulation methods, when the modulation method is changed from the QPSK method to the 16QAM method in consideration of a channel environment and a cell coverage range, it is common that the modulation method is changed one-sidedly without any consideration of whether the subscriber station is busy. In the case in which modulation method is suddenly changed without considering a channel state, a link between subscriber stations communicating with each other is disconnected and the modulation method is changed to a new modulation method. As a result, it takes a long time to reestablish communication.

Additionally, the IEEE 802.16e standard sets the modulation method as one of QPSK, the 16QAM, and the 64QAM depending on a channel environment and a cell coverage range, but it does not specify when the modulation methods should be changed. That is, because the IEEE 802.16e standard does not include a concrete standard indicating when and on what the basis the modulation method is changed, there is a problem in that a user may inappropriately change the modulation method.

Further, according to the conventional IEEE 802.16e standard, when a subscriber station frequently moves from one cell coverage range to an adjacent cell coverage range in boundary areas between the respective cell coverage ranges for the QPSK, the 16QAM, and the 64QAM, frequently, the modulation method is changed to a relevant modulation method set for the respective cell coverage ranges. Accordingly, there is a problem in that the subscriber station, which is located in boundary areas between the cell coverage ranges and is busy, has to wait for a very long time until reconnection and thus cannot communicate through soft channel connection.

### SUMMARY OF THE INVENTION

Accordingly, the present invention has been designed to solve the above-mentioned problems occurring in the prior art, and an object of the present invention is to provide a method for changing a modulation method according to a channel environment and a cell coverage range in a broadband wireless access communication system, which reduces a time required for changing the modulation method without disconnecting communication.

Another object of the present invention is to provide a method for changing a modulation method in a broadband wireless access communication system, which appropriately changes the modulation method and provides more stable communication to an access terminal when the access terminal located in boundary areas between cell coverage ranges is busy.

To accomplish the above and other objects, in accordance with one aspect of the present invention, there is provided a soft method for variably changing a modulation method according to a cell coverage range in a broadband wireless access communication system including an access point and at least one access terminal, the method comprising the steps of: calculating an error rate (E) from channel state information included in a first signal transmitted from the access point; determining whether the error rate (E) is a value between a lower limit value and an upper limit value preset as error rates which can be calculated in an overlap range, the overlap range being a range in which modulation methods of adjacent cell coverage ranges are mixed; calculating a difference value (H) between the error rate (E) of the first signal and an error rate (E1) of a second signal if the error rate (E) lies between the lower limit value and the upper limit value; preparing to change the modulation method when the difference value (H) is within a predetermined range; and changing the modulation method according to whether a receiving power level of a third signal received after the second signal increases or decreases in comparison with those of the first and second signals when a difference value (H2) between the error rate (E1) of the second signal and an error rate (E2) of the third signal exceeds a predetermined value.

Preferably, the lower limit value is 20% and the upper limit value is 25%. Also, the predetermined range for comparison with a magnitude of the difference value (H) is between 1% and 3%. The predetermined value for determining whether the difference value (H2) exceeds the predetermined value is 3%. The modulation method, which can be changed according to the present invention, includes 64QAM, 16QAM and QPSK. The first signal, the second signal, and the third signal are downlink preambles.

In accordance with another aspect of the present invention, there is provided a soft method for variably changing a modulation method according to a cell coverage range in a broadband wireless access communication system including an access point and at least one access terminal when the access terminal moves away from the access point, the method comprising the steps of: calculating an error rate (E) from channel state information included in a first signal which is transmitted from the access point; determining whether the error rate (E) is a value between a lower limit value and an upper limit value preset as error rates which can be calculated in an overlap range, the overlap range being a range in which modulation methods of adjacent cell coverage ranges are mixed; preparing to change the modulation method to a modulation method set for modulation in an adjacent cell coverage range, if the error rate (E) lies between the lower limit value and the upper limit value; and calculating an error rate (E1) from channel state information included in a second signal, and changing the modulation method from the current modulation method to a modulation method set for modulation in an adjacent cell coverage range, if the calculated error rate (E1) exceeds the upper limit value.

According to the present invention, when the access terminal moves away from the access point, an upper limit value and a lower limit value of an error rate of a received signal are set for an access terminal located in a range to which at least two modulation methods can be applied. The current modulation method is maintained when the error rate lies between the upper limit value and the lower limit value, and the current modulation method is changed to a modulation method applied to an adjacent cell coverage range when the error rate exceeds the upper limit value, so that the modulation method of the access terminal can be easily changed.

### BRIEF DESCRIPTION OF THE DRAWINGS

The above and other objects, features, and advantages of the present invention will be more apparent from the following detailed description taken in conjunction with the accompanying drawings, in which:

FIG. 1 illustrates ranges to which modulation methods are applied according to cell coverage ranges;

FIG. 2 illustrates an example of applying a soft modulation changing algorithm when an access terminal moves away from an access point;

FIG. 3 illustrates an example of applying the soft modulation changing algorithm when an access terminal moves near to an access point;

FIG. 4 is a table for modulation/coding information; and

FIGS. 5 and 6 are flowcharts illustrating a modulation changing method according to the present invention.

### DETAILED DESCRIPTION OF THE PREFERRED EMBODIMENT

Hereinafter, preferred embodiments of the present invention will be described in detail with reference to the accompanying drawings. It is to be noted that the same elements are indicated with the same reference numerals throughout the drawings. Although a number of specific features, such as specific components of a circuitry, are given below, they are presented for a better understanding of the present invention only. Also, it will be clear to those skilled in the art that the present invention can be practiced without such specific features. Accordingly, in the following description of the present invention, a detailed description of known functions and configurations incorporated herein will be omitted when it may make the subject matter of the present invention rather unclear.

The present invention is applied by variably changing a modulation method according to a receiving power of an access terminal (AT) and a distance between the access terminal and an access point (AP), when the access terminal is located within a cell coverage range of the access point. Also, according to the present invention, the modulation method is changed depending on a predetermined point of time and distance so as to change the relevant modulation method by using a soft modulation changing algorithm suitable for a wireless channel environment.

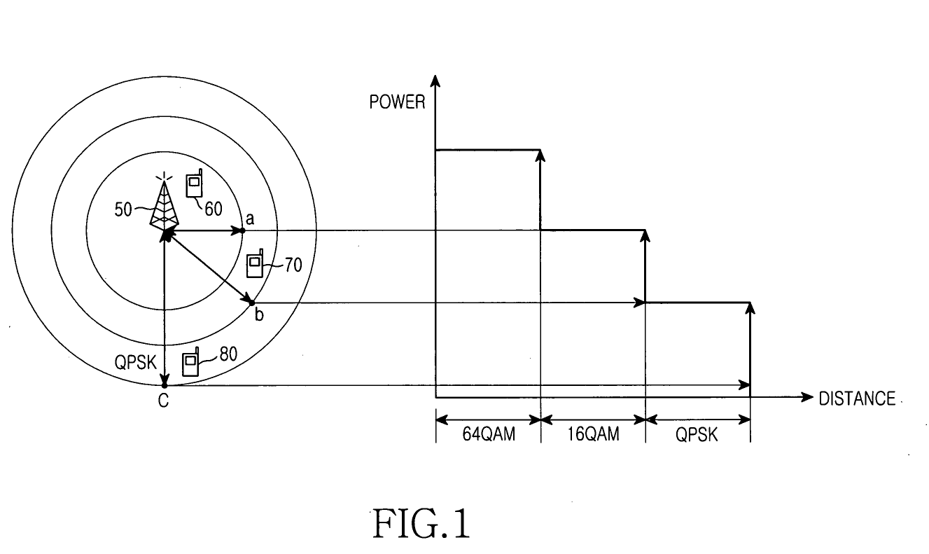

FIG. 1 illustrates ranges to which modulation methods are applied according to cell coverage ranges. When cell coverage ranges are formed as ideal concentric circles whose center is an access point 50, a 64QAM method is applied to a first cell coverage range nearest to the access point 50, a QPSK method is applied to a third cell coverage range farthest away from the access point 50, and a 16QAM method is applied to a second cell coverage range located in a middle region between the two coverage ranges of the 64QAM method and the QPSK method. A lateral axis represents distances between the access point 50 and each access terminal 60, 70, and 80, and a longitudinal axis represents power of a signal transmitted from the access point 50.

Because the number of bits to be transmitted is largest in the 64QAM method, the 64QAM requires large power consumption at the access point 50 for transmitting data to a long distance. Therefore, the 64QAM method is applied in the first cell coverage range nearest to the access point 50.

In FIG. 1, the first cell coverage range of the 64QAM method is represented as a range from the access point 50 to point ‘a’. The second cell coverage range, in which the 16QAM method is applied, is represented as a range between point ‘a’ and point ‘b’. Because the number of bits to be transmitted is fewest in the QPSK method, the QPSK requires relatively less power consumption at the access point 50 for transmitting data to a long distance. Therefore, the 64QAM method is applied in the third cell coverage range (a range between point ‘b’ and point ‘c’) farthest away from the access point 50.

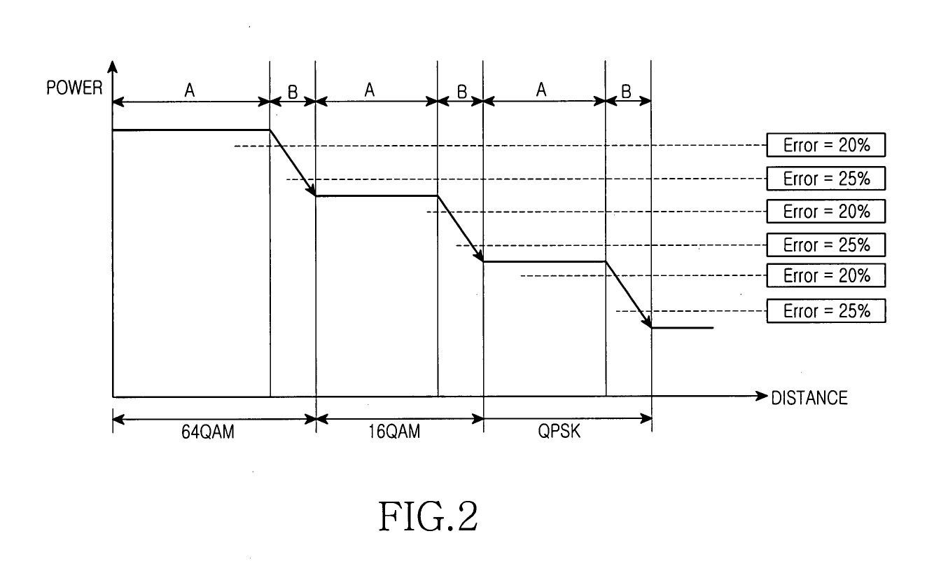

FIG. 2 illustrates an example of applying a soft modulation changing algorithm when an access terminal moves away from an access point. Referring to FIG. 2, an x-axis represents a distance away from the access point and a y-axis represents power of a signal transmitted from the access point. The 64QAM method is applied to the first cell coverage range nearest to the access point, the QPSK method is applied to the third cell coverage range farthest away from the access point, and the 16QAM method is applied to the second cell coverage range between the first and the third cell coverage range.

In FIG. 2, each section ‘A’ represents each cell coverage range to which a relevant modulation method is stably applied, and is a range independent of adjacent cell coverage ranges to which other modulation methods are applied, respectively. However, each section ‘B’ represents an overlap range in which each cell coverage range is overlapped with adjacent cell coverage ranges and two different modulation methods are mixed. ‘Error’ represents a threshold value of an error rate, which becomes a criterion for changing a relevant modulation method to a different modulation method. According to this embodiment, the threshold value of the error rate is set as 20% and 25%, respectively.

Hereinafter, an example of changing modulation methods according to an error rate of a receiving signal in an access terminal, which receives the signal transmitted from an access point, will be described with reference to FIG. 2.

When receiving a 64QAM modulated signal transmitted from the access point, the access terminal checks an error rate of the received signal and compares the checked error rate with predetermined threshold values. If the checked error rate is above the predetermined threshold values, the access terminal changes modulation methods and transmits a request signal, requesting that a signal modulated by the changed modulation method should be transmitted, to the access point. According to the request signal received from the access terminal, the access point determines whether a change of the modulation method is needed. If the modulation method needs changing, the access point transmits signals modulated by the requested modulation method.

More specifically, if an error rate of a signal received by the access terminal is 20% or less, the access terminal maintains the current modulation method, i.e., 64QAM. If the error rate of a signal received into the access terminal is a value between 20% and 25%, the access terminal determines itself to be located in a range in which the 64QAM method and the 16QAM method are overlapped with each other, and maintains the 64QAM method.

If the error rate of a signal received by the access terminal exceeds 25%, the access terminal changes the modulation methods to the 16QAM method and transmits a request signal, requesting that a signal modulated by the 16QAM method should be transmitted, to the access point. The access terminal receives a signal modulated by the 16QAM method and checks an error rate of the received signal. If the error rate of the received signal, which is modulated by the 16QAM method, is 20% or less, the access terminal maintains the current modulation method, i.e., 16QAM. If the error rate of the received signal is a value between 20% and 25%, the access terminal determines itself to be located in a range in which the 16QAM method and the QPSK method are overlapped with each other, and maintains the 16QAM method.

However, if the error rate of the received signal, which is modulated by 16QAM method, exceeds 25%, the access terminal changes the modulation methods to the QPSK method. The access terminal receives a signal modulated by the QPSK method and checks an error rate of the received signal. If the error rate of the received signal, which is modulated by the QPSK method, is 20% or less, the access terminal maintains the current modulation method, i.e., QPSK. If the error rate of the received signal is a value between 20% and 25%, the access terminal also maintains the QPSK method.

Therefore, when the access terminal moves away from the access point, an upper limit value and a lower limit value of an error rate of a received signal are set for an access terminal located in a range to which at least two modulation methods can be applied, the current modulation method is maintained when the error rate lies between the upper limit value and the lower limit value, and the current modulation method is changed to a modulation method applied to an adjacent cell coverage range when the error rate exceeds the upper limit value, so that the modulation method of the access terminal can be easily changed.

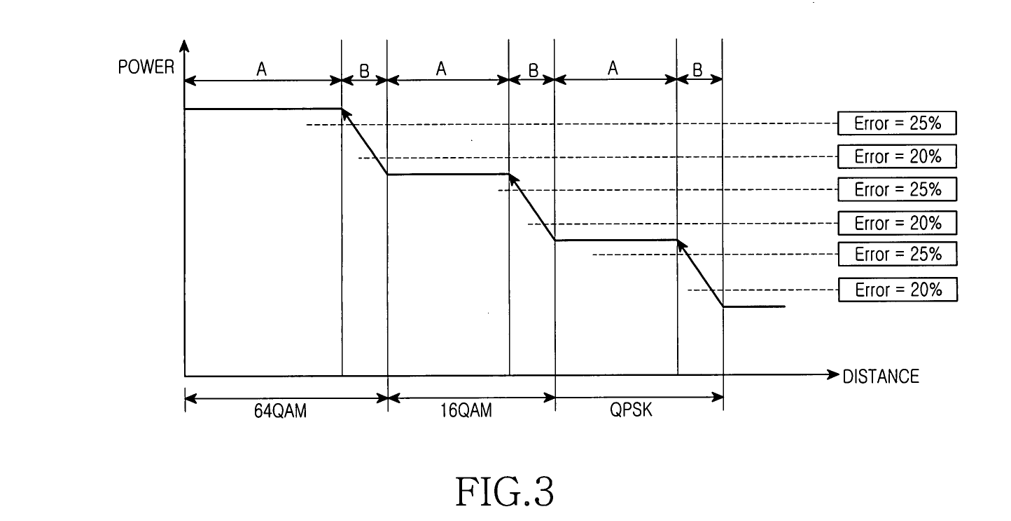

FIG. 3 illustrates an example of applying the soft modulation changing algorithm when an access terminal moves near to an access point. In FIG. 3, the thresholds value of the error rate, which are a criterion for changing modulation methods from one to another, are set as 20% and 25%. When receiving a QPSK modulated signal transmitted from the access point, the access terminal checks an error rate of the received signal and determines whether a change of the modulation methods is needed. That is, if the error rate of the received signal is 20% or less, the access terminal maintains the current modulation method, i.e., QPSK. If the error rate of the received signal is a value between 20% and 25%, the access terminal determines itself to be located in a range in which the QPSK method and the 16QAM method are overlapped with each other, and maintains the QPSK method.

However, if the error rate of the received signal, which is modulated by QPSK method, exceeds 25%, the access terminal changes the modulation methods to the 16QAM method. The access terminal receives a signal modulated by the 16QAM method and checks an error rate of the received signal to determine whether a change of the modulation methods is needed. If the error rate of the received signal, which is modulated by the 16QAM method, is 20% or less, the access terminal maintains the current modulation method, i.e., 16QAM. If the error rate of the received signal is a value between 20% and 25%, the access terminal determines itself to be located in a range in which the 16QAM method and the 64QAM method are overlapped with each other, and maintains the 16QAM method.

If the error rate of the received signal, which is modulated by 16QAM method, exceeds 25%, the access terminal changes the modulation methods to the 64QAM method. The access terminal receives a signal modulated by the 64QAM method and checks an error rate of the received signal. If the error rate of the received signal, which is modulated by the 64QAM method, is 20% or less, the access terminal maintains the current modulation method, i.e., 64QAM. If the error rate of the received signal is a value between 20% and 25%, the access terminal also maintains the 16QAM method. While maintaining the 64QAM method, when the error rate of the received signal becomes more than 25%, the access terminal changes the modulation methods to the 16QAM method.

Therefore, when the access terminal moves nearer to the access point, an upper limit value and a lower limit value of an error rate of a received signal are set for an access terminal located in a range to which at least two modulation methods can be applied, the current modulation method is maintained when the error rate lies between the upper limit value and the lower limit value, and the current modulation method is changed to a modulation method applied to an adjacent cell coverage range when the error rate exceeds the upper limit value, so that the modulation method of the access terminal can be easily changed.

Hereinafter, operation procedures of applying a soft modulation changing algorithm to an access terminal will be described referring to FIGS. 2 and 3. The operation of this embodiment will be described assuming a case in which a downlink preamble exists, because the IEEE 802.16e standard supports the downlink preamble.

When receiving a downlink preamble, the access terminal confirms a downlink (DL) frame prefix in a first downlink frame. The downlink frame prefix includes information about modulation/coding (Rate_ID), OFDM symbol number (No_OFDM_symbols), sub-channel number (No_subchannels), and channel state (prefix_CS). The modulation/coding information is information by which the access point notifies modulation/coding, which the access terminal uses in a downlink map.

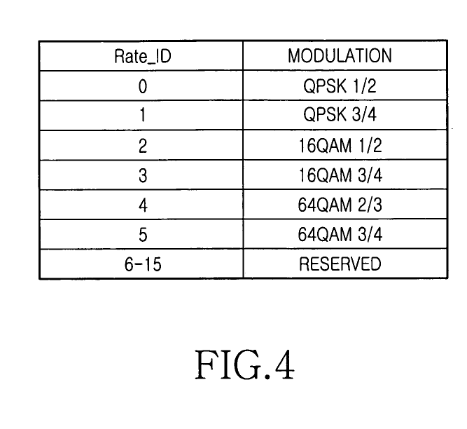

FIG. 4 is a table illustrating modulation/coding information. Referring to FIG. 4, when modulation/coding information in a downlink preamble received from the access point by the access terminal is ‘0’, a received signal is modulated by QPSK 1/2 method.

When modulation/coding information in a downlink preamble received from the access point by the access terminal is ‘2’, a received signal is modulated by 16QAM 1/2 method. Also, when a modulation/coding information in a downlink preamble received from the access point by the access terminal is ‘4’, a received signal is modulated by 64QAM 2/3 method.

The OFDM symbol number information (No_OFDM_symbols) is information by which, for a downlink map message (DL_MAP_message) beginning with a first symbol of a frame, the access point notifies the access terminal of the number of OFDM symbols. The sub-channel number information (No_subchannels) is information by which, for a downlink map message (DL_MAP_message) beginning with sub-channel No. ‘0’, the access point notifies the access terminal of the number of sub-channels. The channel state information (Prefix_CS) is information that is sent from the access point to the access terminal and that the access terminal uses for detecting error in a received signals.

The access terminal uses Equation 1 to detect an error of a received signal.
g(D)=D\hat{ }8+D\hat{ }2+D+1, Equation 1

In Equation 1, g(D) is a value generated by a cycle code and an output value of 8 bits is generated for an input value of 24 bits in this embodiment. This can be represented as (n, k)=(8, 24).

The access terminal obtains knowledge of a modulation method corresponding to a received signal by confirming the modulation/coding information (Rate_ID), and confirms an error according to the current channel state obtained by channel state information (Prefix_CS).

Next, the access terminal compares an error rate confirmed by the channel state information with two threshold values, which have 20% and 25% as a lower limit value and an upper limit value, respectively. If the error rate is a value between the threshold values, 20% and 25%, the access terminal determines itself to be located in an overlap range ‘B’ as illustrated in FIGS. 2 and 3. If an error rate confirmed by the channel state information is less than 20%, the access terminal determines itself to be located in a stable range ‘A’. However, if an error rate confirmed by channel state information exceeds 25%, the access terminal determines that either the channel state is bad or the access terminal itself is located in an adjacent cell coverage range using another modulation method.

An access terminal moving away from the access point shows states as illustrated in FIG. 2. When the access terminal moves away from a cell coverage range of a modulation method currently used, the error rate calculated by the channel state information increases, approaching 25%, which is the upper limit value of the threshold value. That is, the access terminal moves from an overlap range, in which the access terminal is currently located, to a long-distanced cell coverage range to which a modulation method for a wider cell coverage range is applied.

Because the access terminal moves, the error rate continuously changes. Until the error rate exceeds 25%, the access terminal compares a current calculated error rate with a previous calculated error rate. If the difference between a current calculated error rate and a previous calculated error rate is equal to or more than 1% and is less than 3%, the access terminal is still located in the overlap range, so that a currently used modulation method is continuously used. However, because the access terminal can presuppose that a new modulation method has been applied, the access terminal prepares to change a modulation/demodulation method to a modulation/demodulation method used in an adjacent cell coverage range.

If the difference between a current calculated error rate and a previous calculated error rate is 3% or more, the access terminal employs a new modulation/demodulation method because it approaches the adjacent cell coverage range. At this time, the access terminal checks a power of a received signal in a relevant cell and checks whether the power of the received signal increases or decreases. If the power of the received signal decreases, the access terminal shifts to a modulation/demodulation method, which is applied for a longer distance than an application distance of the currently used method. At this time, the access terminal transmits a request signal to the access point, requesting that a signal should be modulated by the changed modulation/demodulation method and then be transmitted. When receiving the request signal, the access terminal modulates a signal by a modulation method requested from the access terminal and transmits the modulated signal.

Therefore, by checking an error rate and a power level of a received signal, receiving and demodulating a signal, which will be modulated by a modulation method to be applied in a next step, and preparing to modulate the signal by the modulation method to be applied in the next step according to the soft modulation changing algorithm, it is easier for the access terminal to apply a new modulation method without a time delay caused by disconnecting communication and changing a modulation method.

An access terminal moving nearer to the access point shows states as illustrated in FIG. 3. When the access terminal moves away from a cell coverage range of a modulation method currently used, the error rate increases, approaching 25%, which is the upper limit value of the threshold values. That is, the access terminal moves from an overlap range in which the access terminal is currently located to a short-distance cell coverage range to which a modulation method for a narrower cell coverage range is applied. The soft modulation changing algorithm as described above will be applied to the subsequent operations.

If receiving power in a cell increases, the access terminal changes modulation/demodulation method to a modulation/demodulation method applied for a shorter distance than an application distance of the currently used method, and the access terminal transmits a request signal to the access point, requesting that a signal should be modulated by the changed modulation/demodulation method and then be transmitted.

Because the threshold values presented in this embodiment vary with a channel environment, appropriate values obtained through experiments can be variably applied according to a channel environment. In order to remove sudden changes of the modulation method and vagueness of the changes in the boundary areas as illustrated in FIG. 1, stable ranges ‘A’ and overlap ranges ‘B’ are divided by setting hysteresis ranges. Threshold values according to the respective modulation methods are set using error rates, which depend on channel state information as illustrated in FIGS. 2 and 3.

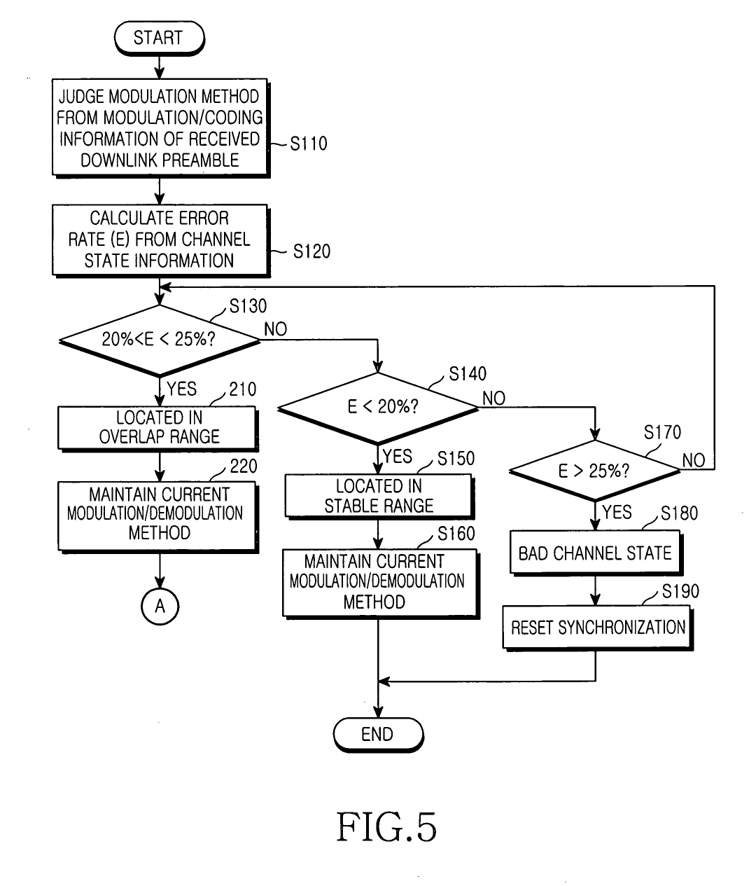

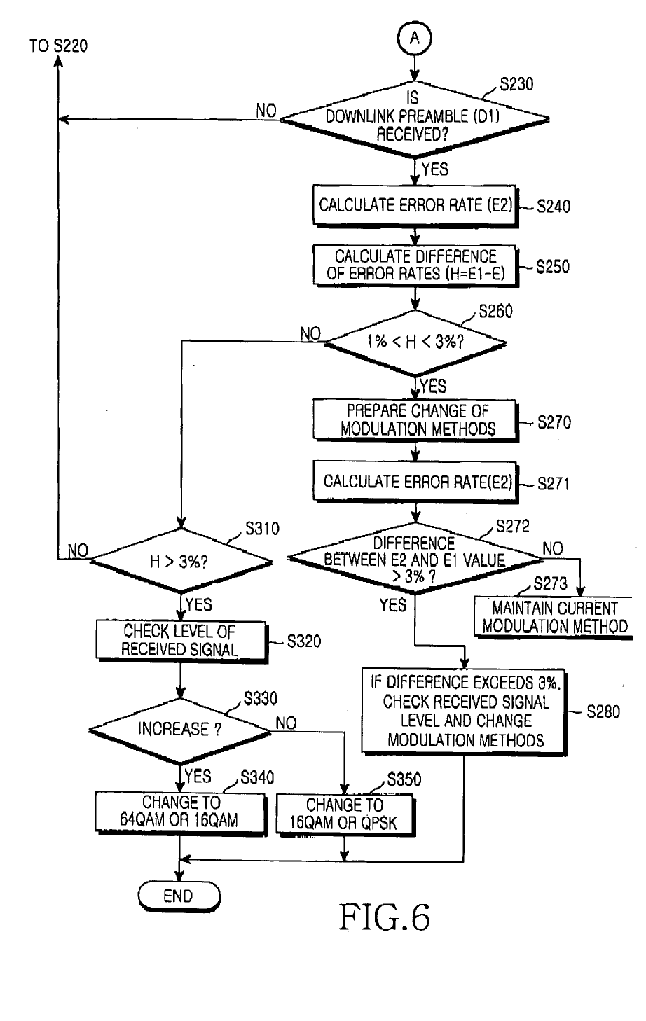

FIGS. 5 and 6 are flowcharts illustrating a modulation-method changing method according to the present invention. Referring to FIGS. 5 and 6, initially, the access terminal receives a downlink preamble (D) transmitted from the access point. In step S110, the access terminal determines a modulation method of a received signal by modulation/coding information included in the received downlink preamble (D). In step S120, the access terminal calculates an error rate (E) from channel state information included in the downlink preamble (D). In step S130, the access terminal determines whether the calculated error rate (E) is a value between 20% and 25%, which are a lower limit value and an upper limit value of predetermined threshold values, respectively.

If the error rate (E) is determined not to be a value between 20% and 25%, the access terminal determines whether the error rate (E) is less than 20% in step S140. If the error rate (E) is determined to be less than 20%, the access terminal determines itself to be located in a stable range in step S150 and maintains the current modulation/demodulation method in step S160.

However, if the error rate (E) is determined to be less than 20% in step S140, the access terminal determines whether the error rate (E) exceeds 25% in step S170. If the error rate (E) is determined to exceed 25%, the access terminal determines a channel state to be bad in step S180, and resets synchronization with the access point in step S190.

If the error rate (E) is determined to be between 20% and 25% in step S130, the access terminal determines itself to be located in an overlap range in step S210 and maintains a current modulation/demodulation method in step 220.

Referring to FIG. 6, after step 220, the access terminal determines whether a downlink frame (D1) is received in the access terminal in step S230. If the downlink frame (D1) is not received, the access terminal maintains the current modulation/demodulation method in step S220. If the downlink frame (D1) is received, the access terminal calculates an error rate (E1) of the downlink frame (D1) in step S240. The access terminal also calculates a difference value (H) between a previous calculated error rate (E) and a current calculated error rate (E1) in step S250.

In step S260, the access terminal determines if the difference value (H) between the error rates (E and E1) is a value between 1% and 3%. If the difference value (H) is a value between 1% and 3%, the access terminal prepares to change modulation/demodulation methods in step S270.

In step S271, when another downlink frame (D2) is received in the access terminal, the access terminal calculates an error rate (E2) of the received downlink frame (D2), and determines if a difference value between a current calculated error rate (E2) and a previous calculated error rate (E1) exceeds 3% in step S272. In step S280, if the difference value exceeds 3%, the access terminal checks whether a power level of a received signal increases or decreases and changes the modulation method accordingly. If the difference value does not exceed 3%, the current modulation method is maintained in step S273. However, in order to change the current modulation method to another one, the terminal always maintains a standby status in an area where a plurality of modulation methods coexist.

When a power level of a received signal increases, the access terminal changes the modulation methods to the 64QAM method or the 16QAM method. More specifically, when a power level of a received signal increases, the access terminal changes the modulation methods to the 64QAM method when a current modulation method is the 16QAM method, or to the 16QAM method when a current modulation method is the QPSK method.

In step S260, if it is determined that the difference value (H) is not between 1% and 3%, the access terminal determines if the difference value (H) exceeds 3% in step S310. If it is determined that the difference value (H) does not exceed 3%, the access terminal maintains a current modulation/demodulation method in step S220. However, if it is determined that the difference value (H) exceeds 3%, the access terminal checks a power level of a received signal in step S320. The access terminal determines whether a receiving power level of the downlink frame (D1) increases or decreases in comparison with that of a previous received downlink preamble (D) in step S330.

If it is determined that the receiving power level of the downlink frame (D1) increases from a previous received downlink preamble (D) in step S330, the access terminal changes the modulation methods to the 64QAM method or the 16QAM method in step 340. However, if it is determined that the receiving power level of the downlink frame (D1) decreases from a previous received downlink preamble (D) in step S330, the access terminal changes the modulation methods to the 16QAM method or the QPSK method in step S350.

Therefore, by softly applying and changing the modulation method according to a receiving error rate of a received signal in a relevant modulation method and a difference between error rates of adjacent received signals, and according to whether a power level of a received signal increases or decreases, it is possible to maintain a stable communication state and to reduce a reset time accompanied by changing the modulation method.

According to the present invention, when the access terminal moves away from the access point, an upper limit value and a lower limit value of an error rate of a received signal are set for an access terminal located in a range to which at least two modulation methods can be applied, the current modulation method is maintained when the error rate lies between the upper limit value and the lower limit value, and the current modulation method is changed to a modulation method applied to an adjacent cell coverage range when the error rate exceeds the upper limit value. As a result, the modulation method of the access terminal can be easily changed.

Further, by checking an error rate and a power level of a received signal, receiving and demodulating a signal, which will be modulated by a modulation method to be applied in a next step, and preparing to modulate the signal by the modulation method to be applied in the next step according to the soft modulation changing algorithm, the access terminal can more easily apply a new modulation method without a time delay caused by disconnecting communication and changing a modulation method.

While the present invention has been shown and described with reference to certain preferred embodiments thereof, it will be understood by those skilled in the art that various changes in form and details may be made therein without departing from the spirit and scope of the present invention as defined by the appended claims.

1. A soft method for variably changing a modulation method according to a cell coverage range in a broadband wireless access communication system including an access point and at least one access terminal, the method comprising the steps of:
calculating an error rate (E) from channel state information included in a first signal transmitted from the access point;
determining whether the error rate (E) is a value between a lower limit value and an upper limit value;
calculating a difference value (H) between the error rate (E) of the first signal and an error rate (E1) of a second signal, if the error rate (E) lies between the lower limit value and the upper limit value;
preparing to change the modulation method when the difference value (H) is within a predetermined range; and
changing the modulation method according to whether a receiving power level of a third signal differs in comparison with receiving powers of the first and second signals, when a difference value (H2) between the error rate (E1) of the second signal and an error rate (E2) of the third signal exceeds a predetermined value.

2. The method as claimed in claim 1, wherein the lower limit value and the upper limit value are preset as error rates, which can be calculated in an overlap range.

3. The method as claimed in claim 2, wherein the overlap range is a range in which modulation methods of adjacent cell coverage ranges are mixed.

4. The method as claimed in claim 3, wherein the lower limit value is 20% and the upper limit value is 25%.

5. The method as claimed in claim 4, wherein the predetermined range for comparison with a magnitude of the difference value (H) is between 1% and 3%.

6. The method as claimed in claim 5, wherein the predetermined value for determining whether the difference value (H2) exceeds the predetermined value is 3%.

7. The method as claimed in claim 1, wherein if the receiving power level of the third received signal is larger than that of the second received signal, a current modulation method is maintained.

8. The method as claimed in claim 1, wherein if the receiving power level of the third received signal is smaller than that of the second received signal, a current modulation method is changed to another modulation method.

9. The method as claimed in claim 1, wherein the modulation method that can be changed includes at least one of 64QAM, 16QAM, and QPSK.

10. The method as claimed in claim 1, wherein at least one of the first signal, the second signal, and the third signal is a downlink preamble.

11. A soft method for variably changing a modulation method according to a cell coverage range in a broadband wireless access communication system including an access point and at least one access terminal, when the at least one access terminal moves away from the access point, the method comprising the steps of:
calculating an error rate (E) from channel state information included in a first signal transmitted from the access point;
determining whether the error rate (E) is a value between a lower limit value and an upper limit value;
preparing to change the modulation method to an adjacent modulation method set in an adjacent cell coverage range, if the error rate (E) lies between the lower limit value and the upper limit value; and
calculating an error rate (E1) from channel state information included in a second signal, and changing the modulation method from a current modulation method to the adjacent modulation method, if the calculated error rate (E1) exceeds the upper limit value.

12. The method as claimed in claim 11, wherein the lower limit value and the upper limit value are preset as error rates, which can be calculated in an overlap range.

13. The method as claimed in claim 12, wherein the overlap range is a range in which modulation methods of adjacent cell coverage ranges are mixed.

14. The method as claimed in claim 11, wherein the lower limit value is 20% and the upper limit value is 25%.

15. The method as claimed in claim 11, wherein the modulation method that can be changed includes at least one of 64QAM, 16QAM, and QPSK.

16. The method as claimed in claim 11, wherein at least one of the first signal, the second signal, and the third signal is a downlink preamble.
